(19) United States
(12) Patent Application Publication
(10) Pub. No.: US 2024/0186808 A1
(43) Pub. Date: Jun. 6, 2024

(54) STORAGE SYSTEM CONFIGURED FOR USE WITH AN ENERGY MANAGEMENT SYSTEM

(71) Applicant: Enphase Energy, Inc., Petaluma, CA (US)

(72) Inventors: Donald Richard ZIMMANCK, Sebastopol, CA (US); Blake Richard LUNDSTROM, Lakewood, CO (US)

(21) Appl. No.: 18/519,932

(22) Filed: Nov. 27, 2023

Related U.S. Application Data
(60) Provisional application No. 63/430,136, filed on Dec. 5, 2022.

(51) Int. Cl. H02J 7/00; G01R 31/3842; H03H 17/02

(52) U.S. Cl. CPC H02J 7/0048; G01R 31/3842; H02J 7/00712; H03H 17/0257

(57) ABSTRACT

A storage system configured for use with an energy management system is provided herein and comprises a battery, a battery management unit coupled to the battery and a power converter comprising plurality of microinverters operably coupled to the battery and the battery management unit, each microinverter of the plurality of microinverters configured to calculate an estimate of state-of-charge of the battery and periodically communicate a calculated estimate of state-of-charge to the other microinverters, such that each microinverter of the plurality of microinverters calculates an average state-of-charge of the battery and communicates the calculated average state-of-charge to the battery management unit for controlling charging/discharging of the battery.

### CROSS-REFERENCE TO RELATED APPLICATIONS

This application claims the benefit of and priority to U.S. Provisional Application Ser. No. 63/430, 136, filed on Dec. 5, 2022, the entire contents of which is incorporated herein by reference.

### BACKGROUND

### 1. Field of the Disclosure

Embodiments of the present disclosure generally relate to power systems and, more particularly, to methods and apparatus for distributed state-of-charge (SoC) estimation of a battery.

### 2. Description of the Related Art

Conventional AC storage systems comprise one or more batteries (e.g., lithium-ion batteries) and provide a required energy storage (kWh) and a required AC power (KW). Conventional AC storage systems are designed with a battery management unit (BMU) which is responsible for protecting the one or more batteries from faults, balancing the battery cells, and calculating battery telemetry such as the SoC. SoC is an important parameter of the lithium-ion battery in terms of indicating a proper battery state, providing an available energy, for calculating SoH (state-of-health), etc. A high accuracy of the SoC is required (e.g., <2%). Thus, SoC estimation algorithms such as coulomb counting and Kalman filtering rely on having a single voltage and current measurement of a battery pack of the AC storage systems to accurately estimate the SoC during operation.

The single voltage/current measurement requirement can add significant cost and complexity to the BMU, as measuring the large DC currents in the battery packs requires expensive sensors or current shunts, high current terminals, large PCB traces, and expensive analog front-ends to process the signal. Additionally, the chargers/inverters, which typically connect to the one or more batteries, often have individual current measurements. While the current measurements can be transmitted to the BMU using, for example, a communications system and aggregated digitally, if the currents have high frequency content (e.g., such as in a single-phase inverter system), the speed and synchronization requirements for the communications system make using such systems impractical for transmitting the current measurements to the BMU. Accordingly, there is a need to develop a distributed SoC estimation technique which does not rely on high frequency communications.

Therefore, the inventors have found improved methods and apparatus for distributed state-of-charge (SoC) estimation of a battery, without relying on high frequency communications.

### SUMMARY

In accordance with some aspects of the present disclosure, a storage system configured for use with an energy management system comprises a battery, a battery management unit coupled to the battery and a power converter comprising plurality of microinverters operably coupled to the battery and the battery management unit, each microinverter of the plurality of microinverters configured to calculate an estimate of state-of-charge of the battery and periodically communicate a calculated estimate of state-of-charge to the other microinverters, such that each microinverter of the plurality of microinverters calculates an average state-of-charge of the battery and communicates the calculated average state-of-charge to the battery management unit for controlling charging/discharging of the battery.

In accordance with some aspects of the present disclosure, a method for managing a storage system configured for use with an energy management system comprises calculating at each microinverter of a plurality of microinverters an estimate a state-of-charge of a battery, broadcasting from each of the plurality of microinverters a calculated estimate state-of-charge of the battery and when the each microinverter of the plurality of microinverters receives the calculated estimate state-of-charge from other microinverters of the plurality of microinverters, calculating at the each microinverter of the plurality of microinverters an average state-of-charge based on the calculated estimate state-of-charge for controlling charging/discharging of the battery.

In accordance with some aspects of the present disclosure, a non-transitory computer readable storage medium has instructions stored thereon that when executed b a processor performs a method for managing a storage system configured for use with an energy management system. The method comprises calculating at each microinverter of a plurality of microinverters an estimate a state-of-charge of a battery, broadcasting from each of the plurality of microinverters a calculated estimate state-of-charge of the battery and when the each microinverter of the plurality of microinverters receives the calculated estimate state-of-charge from other microinverters of the plurality of microinverters, calculating at the each microinverter of the plurality of microinverters an average state-of-charge based on the calculated estimate state-of-charge for controlling charging/discharging of the battery.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only a typical embodiment of this disclosure and are therefore not to be considered limiting of its scope, for the disclosure may admit to other equally effective embodiments.

FIG. 1 is a block diagram of a system for power conversion, in accordance with at least some embodiments of the present disclosure;

FIG. 2 is a block diagram of an AC battery system, in accordance with at least some embodiments of the present disclosure; and

FIG. 3 is a flowchart of a method for managing a storage system configured for use with an energy management system, in accordance with at least one embodiment of the present disclosure.

### DETAILED DESCRIPTION

In accordance with the present disclosure, methods and apparatus for calculating a state-of-charge (SoC) of a battery of a storage system are disclosed herein. For example, a storage system can be configured for use with an energy management system comprising a battery, a battery management unit coupled to the battery, and a power converter. The power converter can comprise a plurality of microinverters operably coupled to the battery and the battery management unit. Each microinverter of the plurality of microinverters can be configured to calculate an estimate of state-of-charge of the battery and periodically communicate a calculated estimate of state-of-charge to the other microinverters. Each microinverter of the plurality of microinverters can calculate an average state-of-charge of the battery and communicate the calculated average state-of-charge to the battery management unit to control charging/discharging of the battery. The methods and apparatus described herein provide improved distributed SoC estimation techniques that do not rely on high frequency communications.

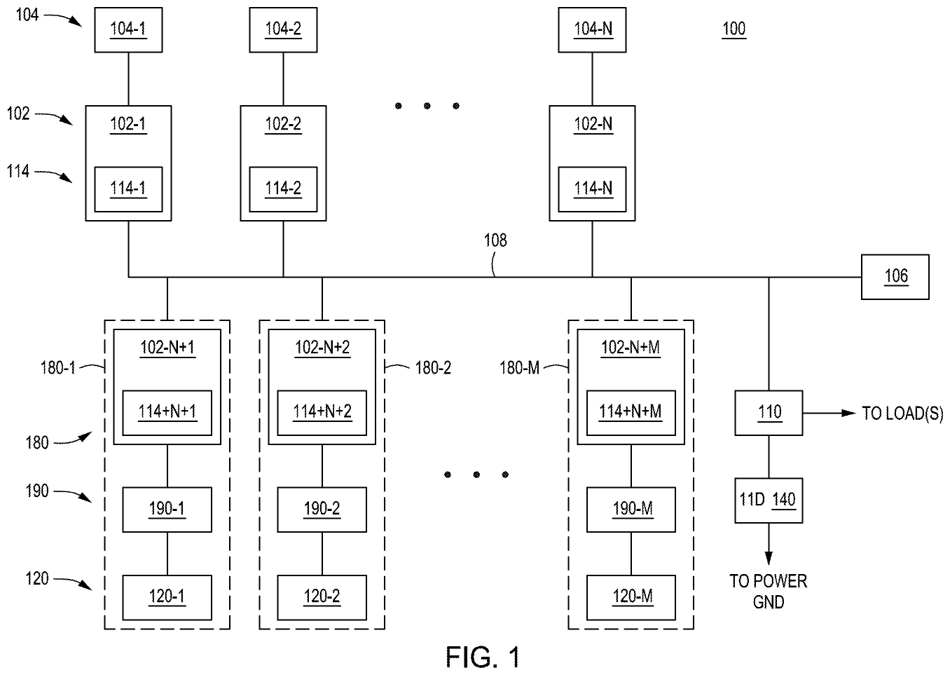

FIG. 1 is a block diagram of a system 100 (energy management system) for power conversion using one or more embodiments of the present disclosure. This diagram only portrays one variation of the myriad of possible system configurations and devices that may utilize the present disclosure.

The system 100 is a microgrid that can operate in both an islanded state and in a grid-connected state (i.e., when connected to another power grid (such as one or more other microgrids and/or a commercial power grid). The system 100 comprises a plurality of power converters 102-1, 102-2, . . . 102-N, 102-N+1, and 102-N+M collectively referred to as power converters 102 (which also may be called power conditioners); a plurality of DC power sources 104-1, 104-2, . . . 104-N, collectively referred to as power sources 104 (e.g., converters); a plurality of energy storage devices/delivery devices 120-1, 120-2, . . . 120-M collectively referred to as energy storage/delivery devices 120; a system controller 106; a plurality of BMUs 190-1, 190-2, . . . 190-M (battery management units) collectively referred to as BMUs 190; a system controller 106; a bus 108; a load center 110; and an IID 140 (island interconnect device) (which may also be referred to as a microgrid interconnect device (MID)). In some embodiments, such as the embodiments described herein, the energy storage/delivery devices are rechargeable batteries (e.g., multi-C-rate collection of AC batteries) which may be referred to as batteries 120, although in other embodiments the energy storage/delivery devices may be any other suitable device for storing energy and providing the stored energy. Generally, each of the batteries 120 comprises a plurality cells that are coupled in series, e.g., eight cells coupled in series to form a battery 120.

Each power converter 102-1, 102-2 . . . 102-N is coupled to a DC power source 104-1, 104-2 . . . 104-N, respectively, in a one-to-one correspondence, although in some other embodiments multiple DC power sources may be coupled to one or more of the power converters 102. The power converters 102-N+1, 102-N+2 . . . 102-N+M are respectively coupled to plurality of energy storage devices/delivery devices 120-1, 120-2 . . . 120-M via BMUs 190-1, 190-2 . . . 190-M to form AC batteries 180-1, 180-2 . . . 180-M, respectively. Each of the power converters 102-1, 102-2 . . . 102-N+M comprises a corresponding controller 114-1, 114-2 . . . 114-N+M (collectively referred to as the inverter controllers 114) for controlling operation of the power converters 102-1, 102-2 . . . 102-N+M.

In some embodiments, such as the embodiment described below, the DC power sources 104 are DC power sources and the power converters 102 are bidirectional inverters such that the power converters 102-1 . . . 102-N convert DC power from the DC power sources 104 to grid-compliant AC power that is coupled to the bus 108, and the power converters 102-N+1 . . . 102-N+M convert (during energy storage device discharge) DC power from the batteries 120 to grid-compliant AC power that is coupled to the bus 108 and also convert (during energy storage device charging) AC power from the bus 108 to DC output that is stored in the batteries 120 for subsequent use. The DC power sources 104 may be any suitable DC source, such as an output from a previous power conversion stage, a battery, a renewable energy source (e.g., a solar panel or photovoltaic (PV) module, a wind turbine, a hydroelectric system, or similar renewable energy source), or the like, for providing DC power. In other embodiments the power converters 102 may be other types of converters (such as DC-DC converters), and the bus 108 is a DC power bus.

The power converters 102 are coupled to the system controller 106 via the bus 108 (which also may be referred to as an AC line or a grid). The system controller 106 generally comprises a CPU coupled to each of support circuits and a memory that comprises a system control module for controlling some operational aspects of the system 100 and/or monitoring the system 100 (e.g., issuing certain command and control instructions to one or more of the power converters 102, collecting data related to the performance of the power converters 102, and the like). The system controller 106 is capable of communicating with the power converters 102 by wireless and/or wired communication (e.g., power line communication) for providing certain operative control and/or monitoring of the power converters 102.

In some embodiments, the system controller 106 may be a gateway that receives data (e.g., performance data) from the power converters 102 and communicates (e.g., via the Internet) the data and/or other information to a remote device or system, such as a master controller (not shown). Additionally or alternatively, the gateway may receive information from a remote device or system (not shown) and may communicate the information to the power converters 102 and/or use the information to generate control commands that are issued to the power converters 102.

The power converters 102 are coupled to the load center 110 via the bus 108, and the load center 110 is coupled to the power grid via the IID 140. When coupled to the power grid (e.g., a commercial grid or a larger microgrid) via the IID 140, the system 100 may be referred to as grid-connected; when disconnected from the power grid via the IID 140, the system 100 may be referred to as islanded. The IID 140 determines when to disconnect from/connect to the power grid (e.g., the IID 140 may detect a grid fluctuation, disturbance, outage or the like) and performs the disconnection/connection. Once disconnected from the power grid, the system 100 can continue to generate power as an intentional island, without imposing safety risks on any line workers that may be working on the grid, using the droop control techniques described herein. The IID 140 comprises a disconnect component (e.g., a disconnect relay) for physically disconnecting/connecting the system 100 from/to the power grid. In some embodiments, the IID 140 may additionally comprise an autoformer for coupling the system 100 to a split-phase load that may have a misbalance in it with some neutral current. In certain embodiments, the system controller 106 comprises the IID 140 or a portion of the IID 140.

The power converters 102 convert the DC power from the DC power sources 104 and discharging batteries 120 to grid-compliant AC power and couple the generated output power to the load center 110 via the bus 108. The power is then distributed to one or more loads (for example to one or more appliances) and/or to the power grid (when connected to the power grid). Additionally or alternatively, the generated energy may be stored for later use, for example using batteries, heated water, hydro pumping, H₂O-to-hydrogen conversion, or the like. Generally, the system 100 is coupled to the commercial power grid, although in some embodiments the system 100 is completely separate from the commercial grid and operates as an independent microgrid.

In some embodiments, the AC power generated by the power converters 102 is single-phase AC power. In other embodiments, the power converters 102 generate three-phase AC power.

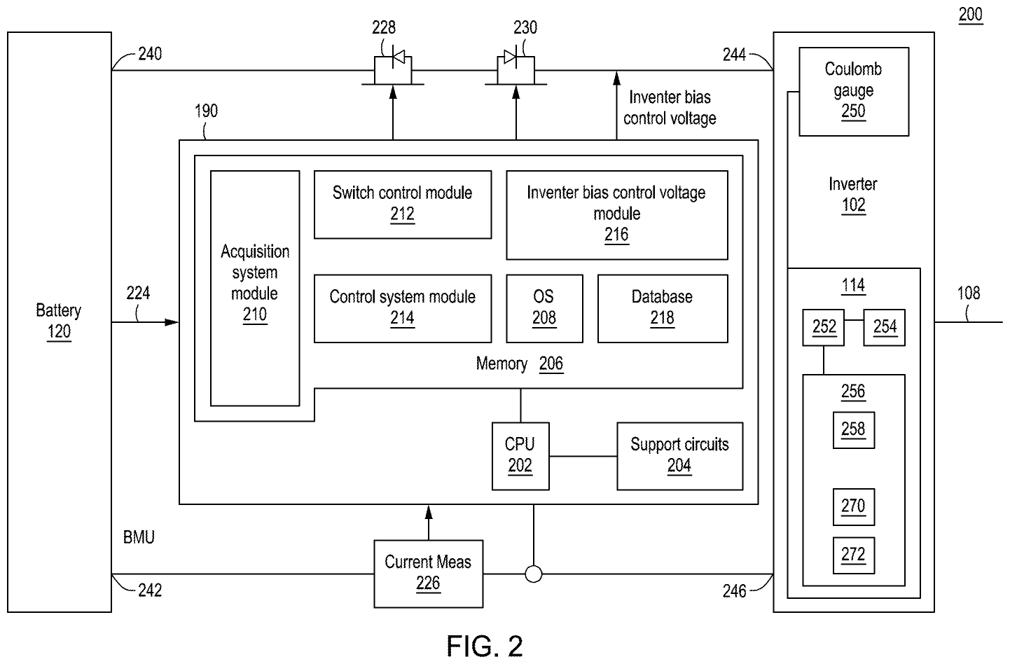

A storage system configured for use with an energy management system, such as the Enphase® Energy System, is described herein. For example, FIG. 2 is a block diagram of an AC battery system 200 (e.g., a storage system) in accordance with one or more embodiments of the present disclosure.

The AC battery system 200 comprises a BMU 190 coupled to a battery (e.g., the battery 120) and one or more inverters (e.g., the power converters 102). In at least some embodiments, the battery 120 can comprise a plurality of cells (not shown) and the power converters 102 can comprise four embedded converters (e.g., four embedded microinverters). In at least some embodiments, the battery 120 can be the IQ Battery 3 (or the IQ Battery 10) and the microinverters can be the IQ8X-BAT microinverters, both available from Enphase®. A pair of metal-oxide-semiconductor field-effect transistors (MOSFETs) switches—switches 228 and 230—are coupled in series between a first terminal 240 of the battery 120 and a first terminal of the inverter 144 such the body diode cathode terminal of the switch 228 is coupled to the first terminal 240 of the battery 120 and the body diode cathode terminal of the switch 230 is coupled to the first terminal 244 of the power converter 102. The gate terminals of the switches 228 and 230 are coupled to the BMU 190.

A second terminal 242 of the battery 120 is coupled to a second terminal 246 of the power converter 102 via a current measurement module 226 which measures the current flowing between the battery 120 and the power converter 102.

The BMU 190 is coupled to the current measurement module 226 for receiving information on the measured current, and also receives an input 224 from the battery 120 indicating the battery cell voltage and temperature. The BMU 190 is coupled to the gate terminals of each of the switches 228 and 230 for driving the switch 228 to control battery discharge and driving the switch 230 to control battery charge as described herein. The BMU 190 is also coupled across the first terminal 244 and the second terminal 246 for providing an inverter bias control voltage (which may also be referred to as a bias control voltage) to the inverter 102 as described further below.

The configuration of the body diodes of the switches 228 and 230 allows current to be blocked in one direction but not the other depending on state of each of the switches 228 and 230. When the switch 228 is active (i.e., on) while the switch 230 is inactive (i.e., off), battery discharge is enabled to allow current to flow from the battery 120 to the power converter 102 through the body diode of the switch 230. When the switch 228 is inactive while the switch 230 is active, battery charge is enabled to allow current flow from the power converter 102 to the battery 120 through the body diode of the switch 228. When both switches 228 and 230 are active, the system is in a normal mode where the battery 120 can be charged or discharged.

The BMU 190 comprises support circuits 204 and a memory 206 (e.g., non-transitory computer readable storage medium), each coupled to a CPU 202 (central processing unit, e.g., processor). The CPU 202 may comprise one or more processors, microprocessors, microcontrollers and combinations thereof configured to execute non-transient software instructions to perform various tasks in accordance with embodiments of the present disclosure. The CPU 202 may additionally or alternatively include one or more application specific integrated circuits (ASICs). In some embodiments, the CPU 202 may be a microcontroller comprising internal memory for storing controller firmware that, when executed, provides the controller functionality described herein. The BMU 190 may be implemented using a general purpose computer that, when executing particular software, becomes a specific purpose computer for performing various embodiments of the present disclosure.

The support circuits 204 are well known circuits used to promote functionality of the CPU 202. Such circuits include, but are not limited to, a cache, power supplies, clock circuits, buses, input/output (I/O) circuits, and the like. The BMU 190 may be implemented using a general purpose computer that, when executing particular software, becomes a specific purpose computer for performing various embodiments of the present disclosure. In one or more embodiments, the CPU 202 may be a microcontroller comprising internal memory for storing controller firmware that, when executed, provides the controller functionality described herein.

The memory 206 may comprise random access memory, read only memory, removable disk memory, flash memory, and various combinations of these types of memory. The memory 206 is sometimes referred to as main memory and may, in part, be used as cache memory or buffer memory. The memory 206 generally stores the OS 208 (operating system), if necessary, of the inverter controller 114 that can be supported by the CPU capabilities. In some embodiments, the OS 208 may be one of a number of commercially available operating systems such as, but not limited to, LINUX, Real-Time Operating System (RTOS), and the like.

The memory 206 stores non-transient processor-executable instructions and/or data that may be executed by and/or used by the CPU 202 to perform, for example, one or more methods for discharge protection, as described in greater detail below. These processor-executable instructions may comprise firmware, software, and the like, or some combination thereof. The memory 206 stores various forms of application software, such as an acquisition system module 210, a switch control module 212, a control system module 214, and an inverter bias control module 216. The memory 206 additionally stores a database 218 for storing data related to the operation of the BMU 190 and/or the present disclosure, such as one or more thresholds, equations, formulas, curves, and/or algorithms for the control techniques described herein. In various embodiments, one or more of the acquisition system module 210, the switch control module 212, the control system module 214, the inverter bias control module 216, and the database 218, or portions thereof, are implemented in software, firmware, hardware, or a combination thereof.

The acquisition system module 210 obtains the cell voltage and temperature information from the battery 120 via the input 224, obtains the current measurements provided by the current measurement module 226, and provides the cell voltage, cell temperature, and measured current information to the control system module 214 for use as described herein.

The switch control module 212 drives the switches 228 and 230 as determined by the control system module 214. The control system module 214 provides various battery management functions, including protection functions (e.g., overcurrent (OC) protection, overtemperature (OT) protection, and hardware fault protection), metrology functions (e.g., averaging measured battery cell voltage and battery current over, for example, 100 ms to reject 50 and 60 Hz ripple), state of charge (SoC) analysis (e.g., coulomb gauge 250 for determining current flow and utilizing the current flow in estimating the battery SoC; synchronizing estimated SOC values to battery voltages (such as setting SoC to an upper bound, such as 100%, at maximum battery voltage; setting SoC to a lower bound, such as 0%, at a minimum battery voltage); turning off SoC if the power converter 102 never drives the battery 120 to these limits; and the like), balancing (e.g., autonomously balancing the charge across all cells of a battery to be equal, which may be done at the end of charge, at the end of discharge, or in some embodiments both at the end of charge and the end of discharge). By establishing upper and lower estimated SoC bounds based on battery end of charge and end of discharge, respectively, and tracking the current flow and cell voltage (i.e., battery voltage) between these events, the BMU 190 determines the estimated SoC.

The inventors have found a new algorithm for determining the SoC on a battery when the battery is being charged/discharged by multiple converters (e.g., multiple power inverters), where each of the multiple converters measures a corresponding voltage/current, but no single aggregate voltage/current measurement is used in an AC battery system 200.

For example, the inventive concepts described herein combine conventional SoC estimation (e.g., calculated by the BMU 190 with a consensus algorithm (e.g., programming a microinverter). For example, each microinverter of the power converter 102 (charger/discharger) is programmed to assume it is operating on a same percentage of a battery (e.g., the battery 120) and that the other converters (e.g., microinverters) are operating at the same power. Each microinverter then generates its own estimate of what the SoC estimation is using a standard technique, e.g., such as at least one of coulomb counting or Kalman Filtering. Each microinverter is configured to periodically broadcast (e.g., via wired and/or wireless communication) a calculated SoC of the battery 120. Thus, when a converters receives a SoC estimation from another converters, the microinverter averages the received SoC with its own SoC estimation. For example, an average of the SoC estimations can be calculated using Equation (1):

$$\\ \begin{matrix}S o {C}_{mine} = \frac{S o {C}_{mine} + S o {C}_{other}}{2} . & ( 1 )\end{matrix}$$

where SoCₘᵢₙₑ is a state-of-charge calculated by one of the microinverters of the power converter 102 and SoCₒₜₕₑᵣ is a state-of-charge calculated by one of the other microinverters of the power converter 102, and 2 is the number of calculated SoC. Thus, if the power converter 102 comprises 4 microinverters, an average of the SoC can be calculated using Equation (1) with the numerator of Equation (1) being SoCₘᵢₙₑ+SoCₒₜₕₑᵣ+SoCₒₜₕₑᵣ+SoCₒₜₕₑᵣ and the denominator of Equation (1) being four (4).

In some embodiments, the algorithm can also use the consensus algorithm to average other calculated parameters that are used as part of the SoC estimation. For example, Kalman Filter based estimation calculates the estimated open-circuit voltage as part of the SoC estimation. In such embodiments, the consensus algorithm can be calculated using to Equation (2):

$$\\ \begin{matrix}{P}_{mine} = \frac{{P}_{mine} + {P}_{other}}{2} , & ( 2 )\end{matrix}$$

where P can be any internal parameter calculated as part of the SoC estimation algorithm.

Continuing with reference to FIG. 2, the inverter controller 114 comprises support circuits 254 and a memory 256, each coupled to a CPU 252 (central processing unit). The CPU 252 may comprise one or more processors, microprocessors, microcontrollers and combinations thereof configured to execute non-transient software instructions to perform various tasks in accordance with embodiments of the present disclosure. The CPU 252 may additionally or alternatively include one or more application specific integrated circuits (ASICs). In some embodiments, the CPU 252 may be a microcontroller comprising internal memory for storing controller firmware that, when executed, provides the controller functionality herein. The inverter controller 114 may be implemented using a general purpose computer that, when executing particular software, becomes a specific purpose computer for performing various embodiments of the present disclosure.

The support circuits 254 are well known circuits used to promote functionality of the CPU 252. Such circuits include, but are not limited to, a cache, power supplies, clock circuits, buses, input/output (I/O) circuits, and the like. The inverter controller 114 may be implemented using a general purpose computer that, when executing particular software, becomes a specific purpose computer for performing various embodiments of the present disclosure. In one or more embodiments, the CPU 252 may be a microcontroller comprising internal memory for storing controller firmware that, when executed, provides the controller functionality described herein.

The memory 256 may comprise random access memory, read only memory, removable disk memory, flash memory, and various combinations of these types of memory. The memory 256 is sometimes referred to as main memory and may, in part, be used as cache memory or buffer memory. The memory 256 generally stores the OS 258 (operating system), if necessary, of the inverter controller 114 that can be supported by the CPU capabilities. In some embodiments, the OS 258 may be one of a number of commercially available operating systems such as, but not limited to, LINUX, Real-Time Operating System (RTOS), and the like.

The memory 256 stores non-transient processor-executable instructions and/or data that may be executed by and/or used by the CPU 252. These processor-executable instructions may comprise firmware, software, and the like, or some combination thereof. The memory 256 stores various forms of application software, such as a power conversion control module 270 for controlling the bidirectional power conversion, and a battery management control module 272.

The BMU 190 communicates with the system controller 106 to perform balancing of the batteries 120 (e.g., multi-C-rate collection of AC batteries) based on a time remaining before each of the batteries are depleted of charge, to perform droop control (semi-passive) which allows the batteries to run out of charge at substantially the same time, and perform control of the batteries to charge batteries having less time remaining before depletion using batteries having more time remaining before depletion, as described in greater detail below.

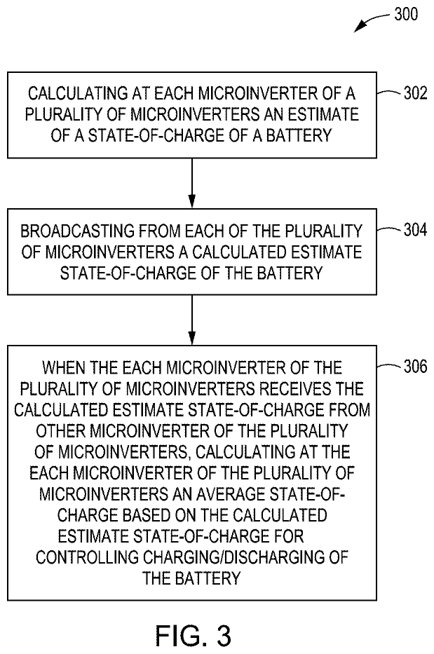

FIG. 3 is a flowchart of a method 300 for managing a storage system configured for use with an energy management system, in accordance with at least one embodiment of the present disclosure. The method 300 can be performed using power converters 102-1 . . . 102-N to convert DC power from the DC power sources 104 to grid-compliant AC power, using the power converters 102-N+1 . . . 102-N+M to convert DC power from the batteries 120 to grid-compliant AC power (e.g., AC-DC power converter), and/or using DC-DC power converters. For illustrative purposes, the method 300 is described configured for use with an AC rechargeable battery and the power converters configured for use with the AC rechargeable battery.

For example, at 302, the method 300 comprises calculating at each of a plurality of microinverters an estimate of a state-of-charge of an AC rechargeable battery. For example, each of the plurality of microinverters of the power converter 102 can calculate an estimate of a SoC of the battery 120. In at least some embodiments, the plurality of microinverters can use coulomb counting and/or Kalman Filtering to calculate estimate of a SoC of the battery 120. In at least some embodiments, the SoC estimation algorithm at 302 is performed on the converters at a frequency of about 200 Hz (e.g., 200 times a second).

Next, at 304, the method 300 comprises broadcasting from each of the plurality of microinverters the calculated state-of-charge of the AC rechargeable battery. For example, each of the plurality of microinverters can broadcast the calculated SoC of the battery 120 via wired or wireless communication. In at least some embodiments, each of the plurality of microinverters can broadcast the calculated SoC of the battery 120 to each other periodically at a predetermined time frame. For example, in at least some embodiments, each of the plurality of microinverters can broadcast the calculated SoC of the battery 120 at 1 Hz (e.g., once a second).

Next, at 306, the method 300 comprises when the each microinverter of the plurality of microinverters receives the calculated estimate state-of-charge from other microinverters of the plurality of microinverters, calculating at the each microinverter of the plurality of microinverters an average state-of-charge based on the calculated estimate state-of-charge for controlling charging/discharging of the battery. For example, depending on how many microinverters the power converter 102 comprises, each of the microinverters of the plurality of microinverters uses Equations (1) and (2) as described above to calculate an average of the received estimate of the state-of-charge. In at least some embodiments, such as when there is four microinverters, one of the microinverters can be designated as a master microinverter that is configured to receive estimates of the state-of-charge from the other three microinverters (slave microinverters), calculate an average of the received estimates of the state-of-charge, and transmit the calculated average to the BMU 190, which, in turn, can control charging/discharging the battery 120 based on the average of the estimates of the state-of-charge and an estimate state-of-charge calculated by the BMU 190. In at least some embodiments, at 306 averaging the received estimate of the state-of-charge with the state-of-charge of the microinverter of the plurality of microinverter can be performed@(N−1) Hz, where N is the number of converters. Thus, when there are a total of four (4) converters, 306 would run three (3) times a second (e.g., every time a message is received from another converter).

While the foregoing is directed to embodiments of the present disclosure, other and further embodiments of the disclosure may be devised without departing from the basic scope thereof, and the scope thereof is determined by the claims that follow.

1. A storage system configured for use with an energy management system, comprising:
a battery;
a battery management unit coupled to the battery; and
a power converter comprising a plurality of microinverters operably coupled to the battery and the battery management unit, each microinverter of the plurality of microinverters configured to calculate an estimate state-of-charge of the battery and periodically communicate a calculated estimate state-of-charge to other microinverters of the plurality of microinverters, such that the each microinverter of the plurality of microinverters calculates an average state-of-charge of the battery and communicates a calculated average state-of-charge to the battery management unit to control charging/discharging of the battery.

2. The storage system of claim 1, wherein the each microinverter of the plurality of microinverters is programmed to operate at a same percentage of the battery.

3. The storage system of claim 1, wherein the average state-of-charge of the battery is calculated using Equation (1):
$$\\ \begin{matrix}S o {C}_{mine} = \frac{S o {C}_{mine} + S o {C}_{other}}{2} , & ( 1 )\end{matrix}$$
where SoCₘᵢₙₑ is the estimate state-of-charge of the battery calculated by the each microinverter of the plurality of microinverters and SoCₒₜₕₑᵣ is an estimate state-of-charge of the battery calculated by the other microinverters of the plurality of microinverters.

4. The storage system of claim 1, wherein the average state-of-charge of the battery is calculated using Equation (2):
$$\\ \begin{matrix}{P}_{mine} = \frac{{P}_{mine} + {P}_{other}}{2} , & ( 2 )\end{matrix}$$
where P is an internal parameter calculated as part of the estimate state-of-charge.

5. The storage system of claim 4, wherein the internal parameter is an open-circuit voltage.

6. The storage system of claim 1, wherein the estimate state-of-charge of the battery is calculated using at least one of coulomb counting or Kalman Filtering.

7. The storage system of claim 1, wherein the power converter is one of an AC-DC power converter or a DC-DC power converter.

8. A method for managing a storage system configured for use with an energy management system, comprising:
calculating at each microinverter of a plurality of microinverters an estimate state-of-charge of a battery;
broadcasting from the each microinverter of the plurality of microinverters a calculated estimate state-of-charge of the battery; and
when the each microinverter of the plurality of microinverters receives the calculated estimate state-of-charge from other microinverters of the plurality of microinverters, calculating at the each microinverter of the plurality of microinverters an average state-of-charge based on the calculated estimate state-of-charge for controlling charging/discharging of the battery.

9. The method of claim 8, further comprising programming the each microinverter of the plurality of microinverters to operate at a same percentage of the battery.

10. The method of claim 8, wherein the average state-of-charge of the battery is calculated using Equation (1):
$$\\ \begin{matrix}S o {C}_{mine} = \frac{S o {C}_{mine} + S o {C}_{other}}{2} , & ( 1 )\end{matrix}$$
where SoCₘᵢₙₑ is the estimate state-of-charge of the battery calculated by the each microinverter of the plurality of microinverters and SoCₒₜₕₑᵣ is an estimate state-of-charge of the battery calculated by the other microinverters of the plurality of microinverters.

11. The method of claim 8, wherein the average state-of-charge of the battery is calculated using Equation (2):
$$\\ \begin{matrix}{P}_{mine} = \frac{{P}_{mine} + {P}_{other}}{2} , & ( 2 )\end{matrix}$$
where P is an internal parameter calculated as part of the estimate state-of-charge.

12. The method of claim 11, wherein the internal parameter is an open-circuit voltage.

13. The method of claim 12, wherein the estimate state-of-charge of the battery is calculated using at least one of coulomb counting or Kalman Filtering.

14. A non-transitory computer readable storage medium having instructions stored thereon that when executed by a processer performs a method for managing a storage system configured for use with an energy management system, comprising:
calculating at each microinverter of a plurality of microinverters an estimate a state-of-charge of a battery;
broadcasting from each of the plurality of microinverters a calculated estimate state-of-charge of the battery; and
when the each microinverter of the plurality of microinverters receives the calculated estimate state-of-charge from other microinverters of the plurality of microinverters, calculating at the each microinverter of the plurality of microinverters an average state-of-charge based on the calculated estimate state-of-charge for controlling charging/discharging of the battery.

15. The non-transitory computer readable storage medium of claim 14, further comprising programming a plurality of microinverters to operate at a same percentage of the battery.

16. The non-transitory computer readable storage medium of claim 14, wherein the average state-of-charge of the battery is calculated using Equation (1):
$$\\ \begin{matrix}S o {C}_{mine} = \frac{S o {C}_{mine} + S o {C}_{other}}{2} , & ( 1 )\end{matrix}$$
where SoCₘᵢₙₑ is the estimate state-of-charge of the battery calculated by the each microinverter of the plurality of microinverters and SoCₒₜₕₑᵣ is an estimate state-of-charge of the battery calculated by the other microinverters of the plurality of microinverters.

17. The non-transitory computer readable storage medium of claim 14, wherein the average state-of-charge of the battery is calculated using Equation (2):
$$\\ \begin{matrix}{P}_{mine} = \frac{{P}_{mine} + {P}_{other}}{2} , & ( 2 )\end{matrix}$$
where P is an internal parameter calculated as part of the estimate state-of-charge.

18. The non-transitory computer readable storage medium of claim 17, wherein the internal parameter is an open-circuit voltage.

19. The non-transitory computer readable storage medium of claim 18, wherein the estimate of state-of-charge of the battery is calculated using at least one of coulomb counting or Kalman Filtering.
